(19) United States
(12) Patent Application Publication
(10) Pub. No.: US 2008/0111123 A1
(43) Pub. Date: May 15, 2008

(54) High Efficiency Light-Emitting Diodes

(75) Inventors: Charles Tu, La Jolla, CA (US); Vladimir Odnoblyudov, La Jolla, CA (US)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: The Regents of the University of California, Oakland, CA (US)

(21) Appl. No.: 11/576,992

(22) PCT Filed: Oct. 8, 2005
(86) PCT No.: PCT/US05/36538

§ 371 Date: Apr. 10, 2007

Related U.S. Application Data
(60) Provisional application No. 60/617,465, filed on Oct. 8, 2004.

(51) Int. Cl. H01L 33/00

(52) U.S. Cl. 257/13; 257/E33.008

(57) ABSTRACT

High efficiency LEDs produced using a direct-bandgap AlGaInNSbAsP material system grown directly on GaP substrates.

### FIELD OF THE INVENTION

The invention relates to high efficiency fight-emitting diodes directly grown on GaP substrates.

### BACKGROUND OF THE INVENTION

Solid-state lighting with light emitting diodes (LEDs) has become one of the most exciting subjects in research and business. Applications for these LEDs include, fall-color displays, signaling, traffic lights, automotive lights and back lighting of cell phones. White LEDs are the ultimate goal, in order to replace incandescent and fluorescent lamps for general lightning. There are three main approaches to produce white light: (1) blue LEDs and yellow phosphor, (2) ultraviolet LEDs and tri-color phosphor, and (3) tri-color mixing from red, green and blue LEDs (RGB approach). The RGB approach is considered to be the most efficient of the three. The three wavelengths for best tri-color mixing are 460 nm, 540 nm and 610 nm. The first two wavelengths, 460 nm and 540 nm, are produced from AlGaInN LEDs, and the last, 610 nm, from AlGaInP-LEDs grown on GaAs substrates. There are several problems with currently used yellow-red AlGaInP based LEDs. The first problem is low internal quantum efficiency and poor temperature stability in the yellow-red range due to poor electron confinement. The second problem is the complicated and high-cost procedure of removing the light-absorbing GaAs substrate and wafer-bonding a transparent GaP substrate or a reflective layer on a carrier.

### SUMMARY OF THE INVENTION

The invention comprises using the direct-bandgap AlGaInNSbAsP material system grown directly on GaP (100) substrates as the active region for yellow-red LEDs. Incorporation of only 0.4% of nitrogen into GaP converts the material from indirect into direct bandgap, and shifts the emission wavelength into the yellow spectral range. Chip processing is much simplified by use of one-step growth on a transparent GaP (100) substrate.

### BRIEF DESCRIPTION OF THE DRAWINGS

FIG. 1 is a depiction of the LED structure of this invention;

FIG. 2 is a schematic of a band diagram of the LED structure of FIG. 1;

FIG. 3(a) depicts the conduction band offset of the InGaNP/GaP-based LED;

FIG. 3(b) depicts the conduction band offset of the AlInGaP/AlGaP-based LED;

FIG. 4(a) is a schematic band diagram of the embedded current spreading/blocking layer,

FIG. 4(b) is an illustration of the current spreading through the structure without current spreading/blocking layer;

FIG. 5 depicts the effect of the annealing photoluminescence properties of the InGaNP quantum well in GaP barriers;

FIG. 6(a) depicts the electroluminescence spectra of the InGaNP-based bare LED chip; and,

FIG. 6(b) depicts the dependence of the emission wavelength vs. the drive current for a commercial AlInGaP-based bare LED chip.

### DETAILED DESCRIPTION OF THE INVENTION

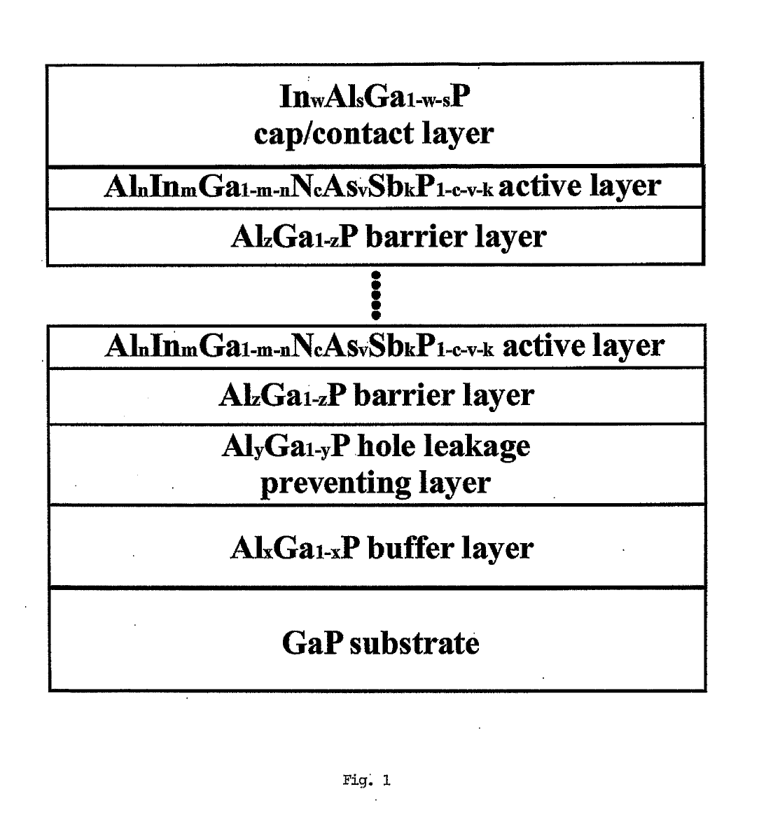

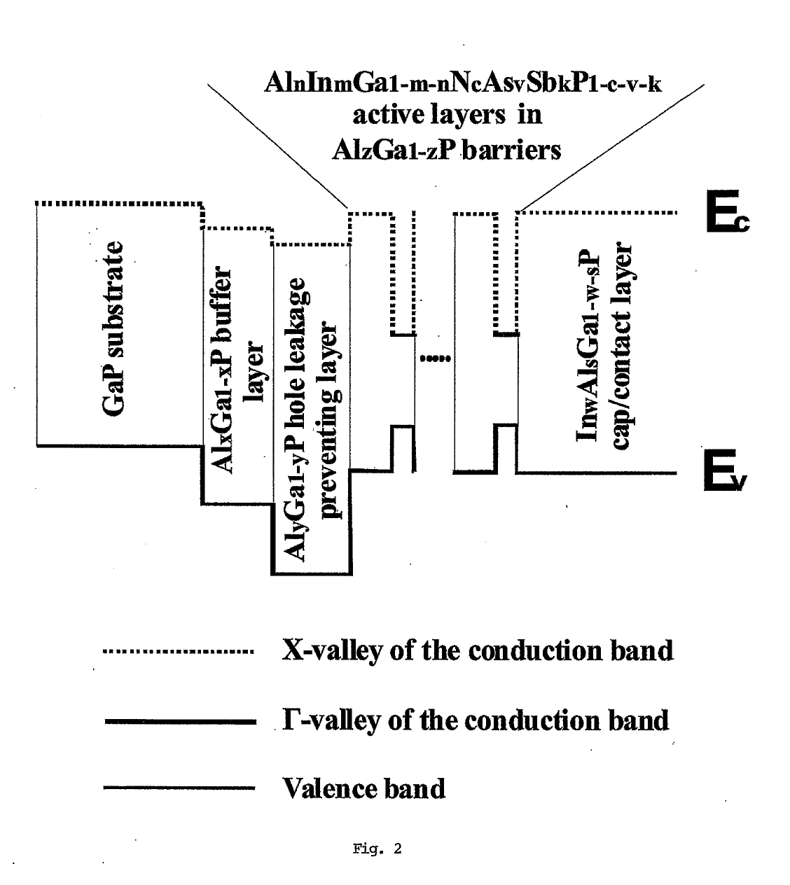

FIG. 1 shows the layer structure of an LED of this invention, FIG. 2 shows a schematic of one of the possible band diagrams for the LED structure of FIG. 1. Referring now to FIGS. 1 and 2:

The first layer grown on a GaP substrate is the AlₓGa₁₋ₓP buffer layer, which is necessary when starting the growth on a substrate in order to obtain a smooth surface for the subsequent growth of the device structure.

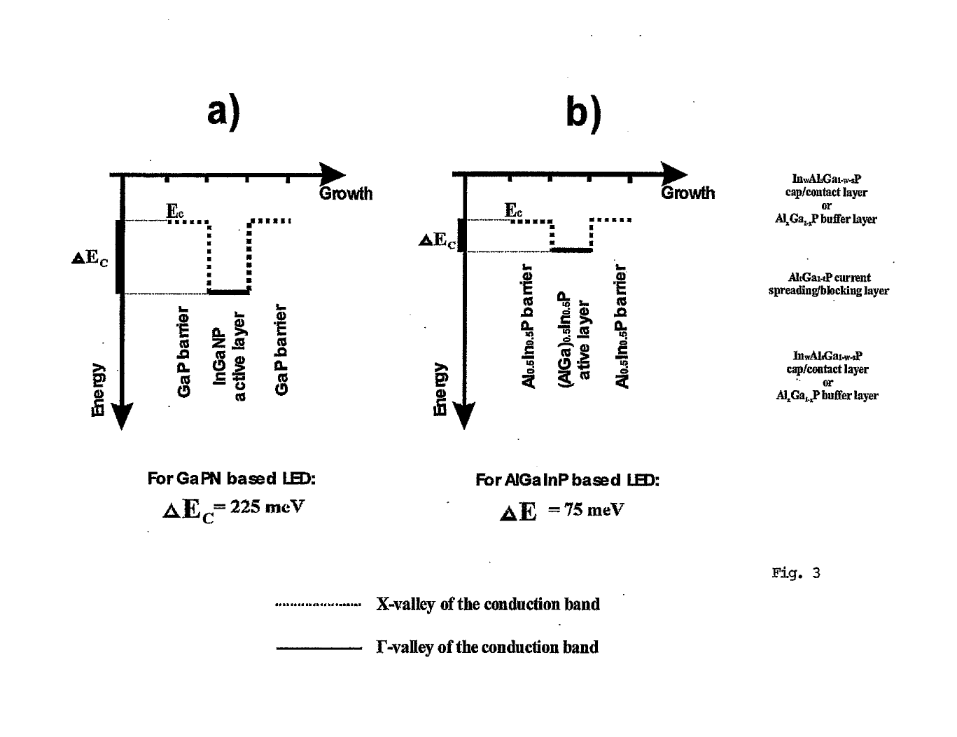

The second layer is the Al_{y}Ga_{1-y}P holes-leakage-preventing layer, whose purpose is to confine the holes in the active region of the structure and to prevent their leakage from the active region. This layer confines only holes, since it forms a type II (“staircase”) heterojunction with the next Al_{z}Ga_{1-z}P barrier layer. The maximum valence band offset can be achieved if AlP material is used as a holes-leakage-preventing layer and GaP material as the barrier layer. The valence band offset in this case is about 500 meV, which is large enough to provide strong confinement for holes in the active layer. Since the conduction band offset between the Al_{z}Ga_{1-z}P barrier layer and the AlₙInₘGa₁₋ₘ₋ₙN_{c}AsᵥSbₖP_{1-c-v-k} active layer is large enough (˜3 times of that for the AlInGaP-based conventional LEDs, shown in FIG. 3) to provide good electron confinement, it is not required to have an extra electron confinement layer outside the active region, as in the case of AlInGaP-based LEDs.

FIG. 3 shows the conduction band diagram for (a) a GaP/InGaNP/GaP and (b) Al_{0.5}In_{0.5}P/(AlGa)_{0.5}In_{0.5}P/Al_{0.5}In_{0.5}P heterostructure. Because GaP and Al_{0.5}In_{0.5}P are indirect-bandgap materials, their conduction band minimum, where electrons reside, is at X-valley at some finite electron momentum, shown by dashed lines. The InGaNP and (AlGa)_{0.5}In_{0.5}P are direct-bandgap materials, so their conduction band minimum, where electrons reside (and their valence band maximum, where holes reside), is at Γ-valley or zero momentum, shown by solid lines. In such heterostractures, electrons would reside in the lower-energy InGaNP or (AlGa)_{0.5}In_{0.5}P active region, and they are confined by the higher-energy GaP or Al_{0.5}In_{0.5}P barriers, respectively. At high temperature, electrons confined in a shallower potential well can acquire enough thermal energy to go over the barrier and are lost to the active region so that light emission from electron-hole recombinations would decrease. Therefore, the larger the potential barrier is, the larger the electron confinement, and the better the high-temperature characteristics of the device.

The third layer is the active region consisting of a plurality of Al_{z}Ga_{1-z}P barrier/AlₙInₘGa₁₋ₘ₋ₙN_{c}AsᵥSbₖP_{1-c-v-k} active layers. The active layer is a direct bandgap material layer. This region is the actual light emitter. Carrier radiative recombination process is going on inside the active layers, separated by the barrier layers. A plurality of these layers is necessary in order to maximize light generation from the carriers injected into the structure.

The last layer is the In_{w}AlₛGa_{1-s-w}P cap/contact layer. This layer is for making external electrode contact for the device, and it separates the active region from the surface, providing better current spreading. Adding indium into the alloy helps to reduce the Shottky barrier between the semiconductor and the metal used for the electrode, thus providing lower contact resistance.

An alternate embodiment utilizes the same structure as FIG. 1, but with an AlₜGa₁₋ₜP (n- or p-type or undoped) current spreading/blocking layer before, inside, or after the In_{w}AlₛGa_{1-s-w}P cap/contact layer, s≦t.

Another alternate embodiment utilizes the same structure as FIG. 1, but with an AlₜGa₁₋ₜP (n- or p-type or undoped) current spreading/blocking layer before, inside, or after the AlₓGa₁₋ₓP buffer layer, x≦t.

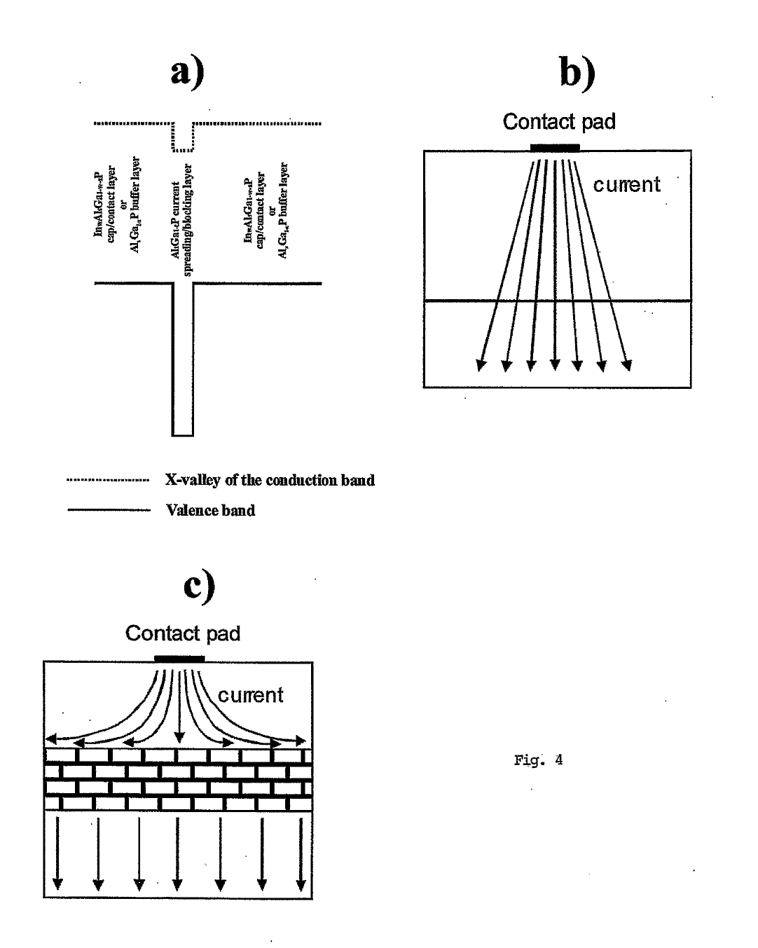

The AlₜGa₁₋ₜP current spreading/blocking layer is used to enhance the electrical and optical properties of the structure. The AlₜGa₁₋ₜP current spreading/blocking layer (FIG. 4a) is a relatively thin layer with a large valence band offset (up to 0.5 eV) with respect to the In_{w}AlₛGa_{1-s-w}P cap/contact layer or the AlₓGa₁₋ₓP buffer layer. It is positioned on the opposite side of the active region from the Al_{y}Ga_{1-y}P holes-leakage-preventing layer. This layer provides a potential barrier for injected holes (FIG. 4a) so that holes can move laterally along the AlₜGa₁₋ₜP current spreading/blocking layer and get over the barrier, providing current spreading from the p-type contact/electrode for more uniform injection of the carriers into the active region. FIG. 4b shows the current in a structure without current spreading/blocking layer. In this case, the current flows into the active region in a “shower-head-like” manner, which provides non-uniform injection. FIG. 4c shows the current in a structure with a current spreading/blocking layer. As shown in this picture, the current spreading/blocking layer allows to spread out current flow and provide uniform injection. The AlₜGa₁₋ₜP current spreading/blocking layer is thick enough to provide current spreading, but yet, thin enough to provide a satisfactory current-voltage characteristic of the diode. The size of the contact pad usually has to be as small as possible, so that it does not cover the surface of the LED, preventing the light from coming out of the device. On the other hand, decreasing the contact pad size may lead to injection of the carriers into a smaller area of the active region of the LED, thus decreasing the light output. There is an optimal contact pad size, which maximizes light output from the LED chip. Enhancement of current spreading under the contact pad is extremely important, since it allows decreasing of the contact pad size while keeping uniform carrier injection, and thus, increasing light output.

An additional embodiment is a variation of the LED structure of FIG. 1, which is the use of n- and p-type delta doping layers deposited on the interfaces between specified layers, or in any place inside the specified layers. These doping layers enhance the current-voltage characteristic of the diode. Delta doping is also called “atomic planar doping”, where dopant atoms are deposited on a growth-interrupted surface. Delta doping provides locally high doping concentrations. Use of delta doping layers reduces or eliminates the potential barrier for carriers at the interfaces of heterojunctions, thus, enhancing current-voltage characteristics.

All of the above described structures as well as separate layers or parts of the layers of the specified structures, may be grown using superlattices or a “digital alloy” technique rather than random alloy. In a random alloy AₓB₁₋ₓC, where A and B atoms occupy one sublattice and C atoms occupy another sublattice, A and B atoms are randomly distributed in the sublattice. In a “digital alloy”, which consists of alternating thin layers of AC/BC/AC/BC, the average composition of A can be made the same as that in the random alloy by adjusting the relative thickness of AC and BC. The layers are thin enough that electrons can move throughout the layers as in a random alloy so that some macroscopic properties of the digital alloy are similar to those of the random alloy. For example, a plurality of AlP/GaP thin layers (digital alloy), rather than a thick AlGaP layer (random alloy), may be preferred because the former can end in a GaP layer, preventing aluminum, which is reactive, from contacting with air.

Another embodiment comprises enhancing the optical properties of the structure by the use, during-growth or post-growth, of annealing, which is heating the substrate to a temperature higher than the maxim temperature used for growth. Several types of recombination processes occur in the active region of an LED chip: radiative recombination, which results in emitting a photon, and several types of non-radiative recombination processes (e.g., via a deep level, via an Auger process), where the energy released during the reaction converts to phonons or heat. In general, one wants to decrease the non-radiative recombination events in the device as much as possible. The most common cause for non-radiative recombination events are defects in the structure, such as deep levels, or non-radiative recombination centers. This is because all defects have energy level structures, different from substitutional semiconductor atoms. Defects include native defects (e.g., vacancies), dislocations, impurities (foreign atoms) and complexes of these.

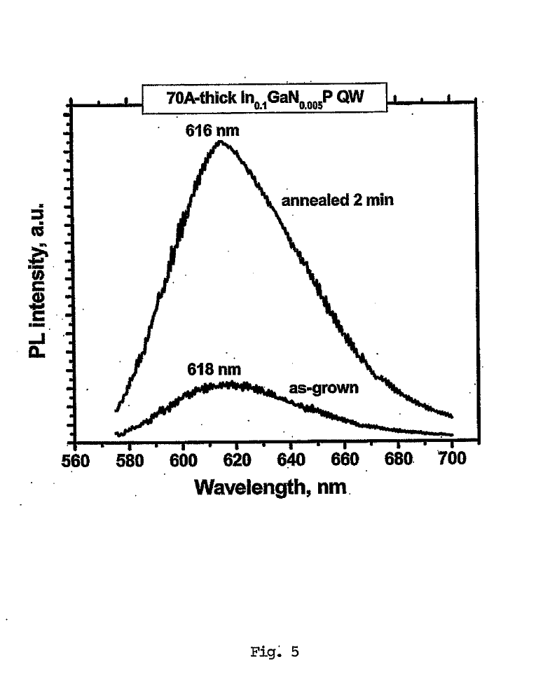

Since the size of the nitrogen atom is much smaller than the size of the other atoms used in the active region, incorporation of nitrogen produces a number of point defects, which tend to trap carriers as non-radiative recombination centers. Thus, these point defects degrade the optical properties of the structure. Annealing helps to reduce the number of point defects in the structure, especially in the nitrogen-containing active region, thus enhancing its radiative efficiency. FIG. 5 shows how annealing increases the photoluminescence intensity of a sample with a 7-nm-thick InGaNP active layer sandwiched between GaP barriers. Annealing here is performed in situ (in the growth chamber) right after growth under a phosphorus overpressure. The annealing temperature is 700° C., and the annealing time is 2 minutes.

### Band Offsets

One of the most important parameters of devices from heterostructures is band offsets (ΔEc and ΔEv) between the active layer and the barrier layers. Usually, a larger ΔEc would result in better device performance. Larger band offsets increase maximum efficiency and improve the temperature stability of the device. The conduction band offset of the LED structure described herein is about 3 times that of the conventional AlInGaP-based LED structure.

For example, the LED structure, with an InGaNP active layer in GaP barriers, emitting at 610 nm has ΔEc=225 meV (FIG. 3a). AlGaInP-based LEDs, which are currently in production, have ΔEc=75 meV for the same wavelength (FIG. 3b). This larger band offset will make the structure have much better temperature stability than the currently used one, e.g., LED chips can operate at higher temperature without decreasing the luminous performance. Increasing the drive current through the device results in the heating of an LED die, since part of the electrical energy transforms into heat. Thus, ambient junction temperature increases, which results in an increase of the thermal energy of the electrons. The active region, where the radiative recombination of the carriers (electrons and holes) occurs, is in fact a potential well for carriers. Increasing of the thermal energy of the electrons due to heating leads to an increase of the number of high-energy electrons, which have sufficient energy to overcome the potential barrier and leave the active region. Electrons which leave the active region do not participate in radiative recombination. This results in a decrease of the luminous performance of the LED chip at higher operating temperatures. Thus, the potential barrier height as high as possible is desired in order to provide better electron confinement in the active region. We have demonstrated 3 times higher conduction band offset for our material system, compared to a conventional AlInGaP material system (see FIG. 3), which results in better luminous performance of the LED chips at higher drive current density or at higher temperature.

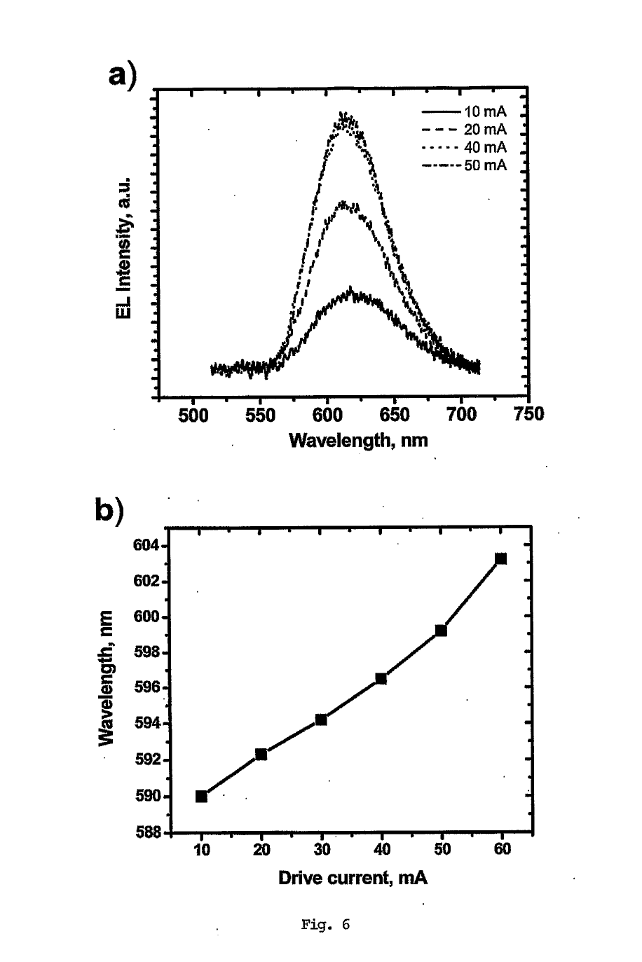

Another advantage of our material system is a weaker temperature dependence of the bandgap of the active region as compared to the AlInGaP material system, which results in better temperature stability of the emission wavelength. As explained above, higher drive current results in increasing the ambient junction temperature. The bandgap of the material decreases, when the crystal temperature is increased. This leads to a red shift of the emission peak wavelength, i.e., the LED chip changes the light emission color when operated at higher drive current. This effect has to be minimized or avoided in order to obtain stable-color LEDs. Experimental data has shown no emission wavelength shift up to 60 mA drive current (FIG. 6a). A commercial AlInGaP-based bare LED chip shows 13 nm of red shift, when the drive current is increased from 10 to 60 mA (FIG. 6b).

### INDUSTRIAL APPLICABILITY

Applications for these LEDs include, full-color displays, signaling, traffic lights, automotive lights and back lighting of cell phones.

Having thus described the invention, we claim:

1. An LED structure comprising the following layers:
a) n-type GaP substrate
b) AlₓGa₁₋ₓP buffer layer n-type or undoped
c) Al_{y}Ga_{1-y}P holes-leakage-preventing layer, n-type or undoped
d) a plurality of the following-layers:
Al_{z}Ga_{1-z}P barrier/AlₙInₘGa₁₋ₘ₋ₙN_{c}AsᵥSbₖP_{1-c-v-k} active layer n- or p-type or undoped, and
e) In_{w}AlₛGa_{1-s-w}P cap/contact layer p-type or undoped

2. The LED structure of claim 1 with compositions x, y, z, n, m, c, v, s, w, k such that: 0≦x≦y≦1, 0≦z, n, m, c, v, s, w, k≦1.

3. An LED structure comprising the following layers:
a) p-type GaP substrate
b) AlₓGa₁₋ₓP buffer layer p-type or undoped
c) a plurality of the following layers:
Al_{z}Ga_{1-z}P barrier/AlₙInₘGa₁₋ₘ₋ₙN_{c}AsᵥSbₖP_{1-c-v-k} active layer n- or p-type or undoped
d) Al_{y}Ga_{1-y}P holes leakage preventing layer n-type or undoped
e) In_{w}AlₛGa_{1-s-w}P cap/contact layer n-type or undoped.

4. The LED structure of claim 1, in which the AlₜGa₁₋ₜP, n-type, p-type or undoped, current spread/blocking layer lies before, inside, or after the In_{w}AlₛGa_{1-s-w}P cap/contact layer.

5. The LED structure of claim 3, in which the AlₜGa₁₋ₜP, n-type, p-type or undoped current spreading/blocking layer lies before, inside, or after the AlₓGa₁₋ₓP buffer layer.

6. The LED structure of claim 1, further comprising n-type or p-type delta doping layers deposited on the interfaces between layers, or any place inside the specified layers.

7. The LED structure of claim 3, further comprising n-type or p-type delta doping layers deposited on the interfaces between layers, or any place inside the specified layers.

8. The LED structure of claim 4, further comprising n-type or p-type delta doping layers deposited on the interfaces between layers, or any place inside the specified layers.

9. The LED structure of claim 5, further comprising n-type or p-type delta doping layers deposited on the interfaces between layers, or any place inside the specified layers.

10. The LED structures of claims 1, 3, 4, or 5 in which the layers, or parts of the layers are grown using the super lattices or “digital alloy” technique.

11. The LED structures of claims 1, 3, 4 or 5 in which improvement of the optical performance is achieved by applying annealing the structures, during or after the growth with an annealing temperature higher than the highest growth temperature used.
